(19) United States
(12) Patent Application Publication
(10) Pub. No.: US 2020/0020799 A1
(43) Pub. Date: Jan. 16, 2020

(54) SEMICONDUCTOR DEVICE AND METHOD OF MANUFACTURING THE SAME

(71) Applicant: RENESAS ELECTRONICS CORPORATION, Tokyo (JP)

(72) Inventors: Yoshiaki UEDA, Ibaraki (JP); Satoru TOKUDA, Ibaraki (JP); Satoshi UCHIYA, Ibaraki (JP); Hiroyoshi KUDOU, Ibaraki (JP)

(21) Appl. No.: 16/446,044

(22) Filed: Jun. 19, 2019

(30) Foreign Application Priority Data
Jun. 28, 2018 (JP) 2018-122675

(51) Int. Cl. H01L 29/78; H01L 29/06; H01L 29/08; H01L 29/417; H01L 29/66; H01L 29/10

(52) U.S. Cl. CPC H01L 29/7813; H01L 29/0696; H01L 29/0865; H01L 21/0274; H01L 29/66727; H01L 29/0882; H01L 29/1095; H01L 29/41741

(57) ABSTRACT

A semiconductor device capable of reducing the influence of noise and easily securing a breakdown voltage between a source wiring and a drain wiring constituting a capacitance between a source and a drain even when shrinkage of a cell progresses, and a manufacturing method thereof are provided. The drain wiring is electrically connected to a substrate region, and the drain wiring is disposed in contact with an upper surface of an interlayer insulating layer. The source wiring is electrically connected to source regions and are disposed in contact with the upper surface of the interlayer insulating layer. A plurality of MOSFET cells are arranged side by side in a X-direction. The drain wiring and the source wiring extends in the X direction and are adjacent to each other in a Y direction crossing the X direction to form a capacitor.

### CROSS-REFERENCE TO RELATED APPLICATIONS

The disclosure of Japanese Patent Application No. 2018-122675 filed on Jun. 28, 2018 including the specification, drawings and abstract is incorporated herein by reference in its entirety.

### BACKGROUND

The present invention relates to a semiconductor device and a method of manufacturing the same.

As a power semiconductor device, for example, a trench-gate type vertical MOSFET (Metal Oxide Semiconductor Field Effect Transistor) is conventionally known.

When noise occurs in such a trench-gate type vertical MOSFET, noise passes through a junction capacitance of the p-n junction formed between a drifting region and a base region. When the frequency of the noise is low, an impedance of the junction capacitance becomes large. As a result, there is a problem that noise does not easily pass through the junction capacitance.

Configurations capable of coping with this problem are disclosed in, for example, Japanese unexamined Patent Application publication No. 2009-260271, Japanese unexamined Patent Application publication No. 2002-528916, and the like.

Each of semiconductor devices disclosed in Japanese unexamined Patent Application publication No. 2009-260211 and Japanese unexamined Patent Application publication No. 2002-528916 has a trench-type vertical MOSFET and a capacitor between a source and a drain. The capacitor constitutes a source-drain capacitance (snubber circuit) between an electrode of a source potential embedded in a trench of a semiconductor substrate and a region connected to a drain electrode. in Japanese unexamined Patent Application, publication No. 2009-260271 and Japanese unexamined Patent Application publication No. 2002-528916, the influence of the noise can be reduced by forming a capacitor between a source and a drain. However, in Japanese unexamined Patent Application publication No. 2009-260271, since capacitor region needs to be separately provided in addition to the MOSFET region, the chip area increases. Further, in Japanese unexamined Patent Application publication No. 2002-528916, since it is necessary to arrange a gate electrode and a source electrode in a trench, the process is complicated.

In Japanese unexamined Patent Application publication No. 2017-163107, a capacitance between a source and a drain is provided above a MOSFET area. Therefore, the increase of the chip area and the complexity of the process can be suppressed.

### SUMMARY

However, in the configuration of the Japanese unexamined Patent Application publication No. 2017-163107, when a planar dimension of a MOSFET cell is reduced for high integration, a distance between a source wiring and a drain wiring constituting a capacitance between a source and a drain are reduced. Therefore, when the shrinkage of the MOSFET cell progresses, a breakdown voltage between the source wiring and the drain wiring may not be ensured.

Other objects and novel features will become apparent from the description of this specification and the accompanying drawings.

A semiconductor device of one embodiment includes a semiconductor substrate, a plurality of cells, a first insulating layer, a drain wiring, and a source wiring. The semiconductor substrate has a first surface and a second surface facing each other. Each of the plurality of cells has a source region disposed on a first surface and a drain region disposed on a second surface. The first insulating layer is disposed on the first surface. The drain wiring is electrically connected to the drain region and is disposed in contact with an upper surface of the first insulating layer. The source wiring is electrically connected to the source region and is disposed in contact with the upper surface of the first insulating layer. The plurality of cells are arranged side by side in a first direction. The drain wiring and the source wiring extend in the first direction and are adjacent to each other in a second direction intersecting the first direction to form a capacitor.

A method of manufacturing a semiconductor device according to an embodiment include following steps. A semiconductor substrate having first and second opposing surfaces is provided. A plurality of cells, each having a source region disposed on a first surface and a drain region disposed on a second surface, are formed in the semiconductor substrate. A first insulating layer is formed on the first surface. Each of a drain wiring electrically connected to the drain region and a source wiring electrically connected to the source region is formed so as to be in contact with an upper surface of the first insulating layer. The plurality of cells are arranged side by side in a first direction. The drain wiring and the source wiring are formed so as to be adjacent to each other in a second direction extending in the first direction and intersecting with the first direction to constitute a capacitor.

According to the above embodiment, it is possible to realize a semiconductor device and a manufacturing method thereof which can reduce the influence of noise and easily secure the breakdown voltage between a source wiring and a drain wiring constituting a capacitance between a source and a drain even when shrinkage of a cell progresses.

### BRIEF DESCRIPTION OF THE DRAWINGS

FIG. 1 is a plan view showing a configuration of a chip state of a semiconductor device according to an embodiment.

FIG. 2 is a plan view showing a layout of a gate electrode, a source wiring, and a drain wiring in a semiconductor device according to an embodiment.

FIG. 3 is a cross-sectional view showing a configuration along a line of FIG. 2.

FIG. 4 is a cross-sectional view showing a configuration along a IV-IV line of FIG. 2,

FIG. 5 is a cross-sectional view showing a configuration along a line V-V in FIG. 2.

FIG. 6 is a cross-sectional view showing a configuration along a VI-VI line of FIG. 2.

FIG. 7 is a cross-sectional view showing a configuration along a VII-VII line of FIG. 2.

FIG. 8 is a plan view showing a state of connection of a source electrode, drain electrode, and a gate wiring in a semiconductor device according to an embodiment.

FIG. 9 is a plan view showing a structure of an upper layer of FIG. 8.

FIG. 10 is a plan view showing a structure of an upper layer of FIG. 9.

FIG. 11 is a plan view showing a structure of an upper layer of FIG. 10.

FIG. 12 is a plan view showing a structure of an upper layer of FIG. 11.

FIG. 13 is a plan view showing a structure of an upper layer of FIG. 12.

FIG. 14 is a cross-sectional view showing a configuration along a XIV-XIV line of FIG. 13.

FIG. 15 is a cross-sectional view showing a configuration along a XV-XV line of FIG. 13.

FIGS. 16A and 16B are cross-sectional views showing a first step of manufacturing method in a semiconductor device according to an embodiment.

FIGS. 17A and 17B are cross-sectional views showing a second step of a manufacturing method in a semiconductor device according to an embodiment.

FIGS. 18A and 18B are cross-sectional views showing a third step of a manufacturing method in. a semiconductor device according to an embodiment.

FIGS. 19A and 19B are cross-sectional views showing a fourth step of a manufacturing method in a semiconductor device according to an embodiment.

FIGS. 20A and 20B are cross-sectional views showing a fifth step of a manufacturing method in a semiconductor device according to an embodiment.

FIGS. 21A and 21B are cross-sectional views showing a sixth step of a manufacturing method in a semiconductor device according to an embodiment.

FIGS. 22A and 22B are cross-sectional views showing seventh step of a manufacturing method in a semiconductor device according to an embodiment. FIGS. 23A and 23B are cross-sectional views showing an eighth step of a manufacturing method in a semiconductor device according to an embodiment.

FIGS. 24A and 24B are cross-sectional views showing a ninth step of a manufacturing method in a semiconductor device according to an embodiment.

FIGS. 25A and 25B are cross-sectional views showing a tenth step of a manufacturing method in a semiconductor device according to an embodiment.

FIGS. 26A and 26E are cross-sectional views showing an eleventh step of a manufacturing method in a semiconductor device according to an embodiment.

FIGS. 27A and 27B are cross-sectional views showing twelfth step of a manufacturing method in a semiconductor device according to an embodiment.

FIG. 28 is an equivalent circuit diagram of a semiconductor device according to an embodiment.

### DETAILED DESCRIPTION

Hereinafter, semiconductor device according to an embodiment of present disclosure will be described with reference to the drawings. In the drawings, the same or corresponding components are denoted by the same reference numerals. Also, at least some of the embodiments described below may be optionally combined.

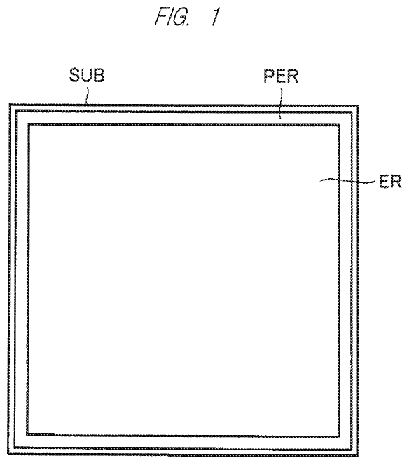

As shown in FIG. 1, a semiconductor device according to the present embodiment includes a semiconductor substrate SUB. For example, a single crystal of silicon (Si) is used for the semiconductor substrate SUB. The semiconductor device in this embodiment has an element region ER and an outer peripheral region PER. The device region ER is a region in which an insulated-gate field-effect transistor (MOSFET) is formed. The outer peripheral region PER is a region located on the outer periphery of the element region ER, and surrounds the element region ER.

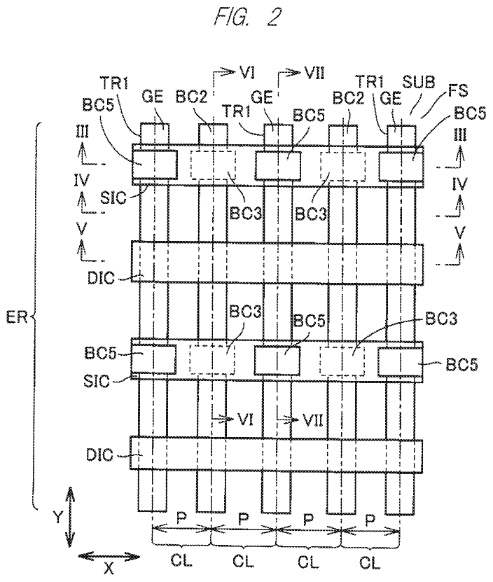

As shown in FIG. 2, a plurality of cells CL are arranged on the semiconductor substrate SUB. Each of the plurality of cells CLs is, for example, a trench-gate type vertical MOSFET. Each of the plurality of MOSFET includes a source region, a drain region, and a gate electrode GE. The plurality of cells CL are arranged on a first surface FS of the semiconductor substrate SUB so as to be aligned in a X direction in the drawing.

A plurality of gate-use trenches TR1 are arranged on the first surface FS of the semiconductor substrate SUB. Gate electrodes GE are buried in each of the plurality of gate trenches TR1. Each of the gate trenches TR1 and the gate electrodes GE extends in a Y direction (second direction) crossing the X direction in which the plurality of cells CL are arranged on the first surface FS. The Y direction is, for example, a direction orthogonal to the X direction.

A plurality of source wiring SIC and a plurality of drain wiring DIC are arranged above the first surface FS of the semiconductor substrate SUB. Each of the plurality of source wiring SICs is electrically connected to a source area of the MOSFET. Each of the plurality of drain regions is electrically connected to the drain region of the MOSFET.

Each of the plurality of source wiring SIC and the plurality of drain wiring DIC extends in the X direction in plan view. The plurality of source wiring SIC and the plurality of drain wiring DIC are arranged so that the source wiring SIC and the drain wiring DIC are alternately arranged in plan view. The source wiring SIC and the drain wiring DIC are adjacent to each other in the Y direction in plan view, thereby forming a capacitor.

In this specification, the plan view means a viewpoint seen from a direction orthogonal to the first surface FS of the semiconductor substrate SUB.

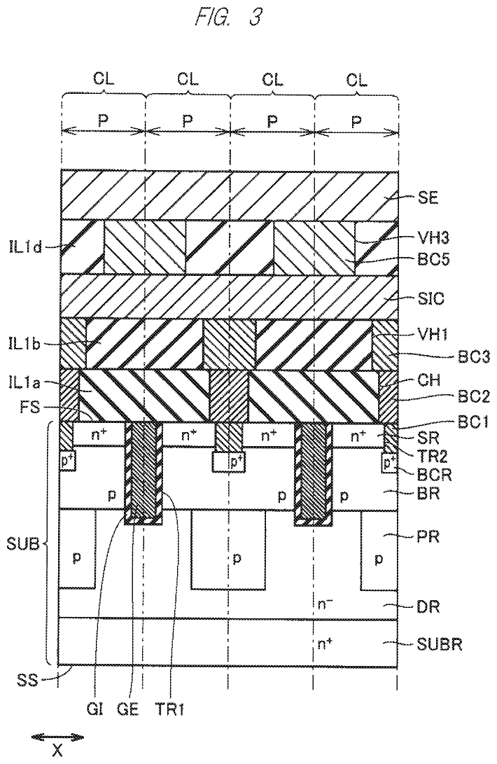

As shown in FIG. 3, the semiconductor substrate SUB has a first surface FS and a second surface SS. The second surface SS faces the first surface FS. In the semiconductor substrate SUB, a plurality of cells CL of trench-gate type and vertical type MOSFET are arranged in the device region ER as described above.

Each of the plurality of MOSFET cells CLs includes a substrate region SUBR, a drifting region DR, a base region ER, a source region SR, gate electrodes GE, and gate insulating layers GI. Each of the plurality of cells CL may include a buried p-type region PR and a base contact region BCR.

The substrate area SUBR is disposed on the second surface of the semiconductor substrate SUB. The substrate region SUBR has n-type conductivity. The substrate region SUBR serves as a drain region of the MOSFET.

The drifting region DR is disposed on the first surface PS-side of the substrate region SUBR. The drift region DR has n-type conductivity, and the drift region DR is in contact with the substrate region SUBR. The concentration of the n-type impurity in the drifting region DR lower than the concentration of the n-type impurity in the substrate region SUBR.

The base region ER is disposed on the first surface FS side of the drift region DR. The base region BR has p-type conductivity, and forms a pn junction with the drift region DR.

The source region SR is disposed on the first surface FS of the semiconductor substrate SUB. The source region SR has n-type conductivity and forms a pn junction with the base region BR. The source region SR sandwiches the base region BR with the drift region DR.

The buried p-type region PR is in contact with the end of the base region BR on the second surface SS side, and extends from the base region BR to the second surface SS side. The buried p-type region PR has p-type conductivity. Each of the side portion of the buried p-type region PR and the end portion on the second surface SS side forms a pn junction with the drift region DR.

The base contact region BCR is formed in the base region BR. The base contact region BCR has p-type conductivity. The concentration of the p-type impurity in the base contact region BCR is high than the concentration of the p-type impurity in the base region BR.

On the first surface FS of the semiconductor substrate SUB, the gate trench TR1 is arranged on the first surface FS the semiconductor substrate SUB. The gate trench TR1 passes through the source region SR and the base region BR from the first surface FS of the semiconductor substrate SUB to reach the drift region DR.

The gate insulating layers GI are arranged along the wall surfaces of the gate trenches TR1, i.e., the side walls and the bottom walls of the gate insulating layers GI. The gate insulating layer GI is made of, for example, silicon oxide, but is not limited to silicon oxide.

The gate electrodes GE are buried in the gate trenches TR1. The gate electrode GE faces the base region BR sandwiched between the source region SR and the drift region DR while being insulated from each other. The gate electrode GE is made of polycrystalline silicon doped with impurities, for example, but is not limited thereto.

A source trench TR2 is disposed on the first surface FS of the semiconductor substrate SUB. The source trench TR2 passes through the source region SR from the first surface FS of the semiconductor substrate SUB to reach the base contact region BCR.

A buried conductive layer BC1 is buried in the source trench TR2. The buried conductive layers BC1 are in contact with both the source region SR and the base contact region BCR.

An interlayer insulating layer IL1a is disposed on the first surface FS of the semiconductor substrate SUB. A contact hole CH is formed in the interlayer insulating layer IL1a. The contact hole CH penetrates the interlayer insulating layer IL1a so as to communicate with the source trench TR2 from the upper surface of the interlayer insulating layer IL1a. A buried conductive layer BC2 is buried in the contact hole CH. The buried conductive layer BC2 is in contact with the buried conductive layer BC1.

Although the buried conductive layer BC1 and the buried conductive layer BC2 are formed as conductive layers differing from each other in the above description, the buried conductive layer BC1 and the buried conductive layer BC2 may be formed of a single conductive layer.

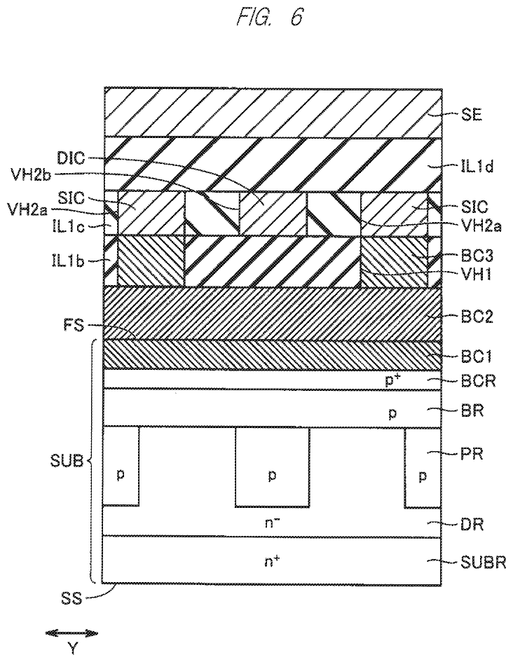

As shown in FIGS. 2 and 6, each of the source trench TR2, the contact hole CH, and the buried conductive layers BC1 and BC2 extends in the Y-direction. The dimensions of the source trench TR2, the contact hole CH, and the buried conductive layers BC1 and BC2 in the Y direction are larger than the dimensions in the X direction.

As shown in FIG. 3, an interlayer insulating layer IL1b is disposed on the upper surface of the interlayer insulating layer IL1a. A via hole VH1 is provided in the interlayer insulating layer IL1b. The via hole VH1 penetrates the interlayer insulating layer IL1b so as to reach the buried conductive layer BC2 from the upper surface of the interlayer insulating layer IL1b. An embedded conductive layer BC3 (the second buried conductive layer) is embedded in the via hole VH1. The buried conductive layer BC3 is in contact with the buried conductive layer BC2.

As shown in FIG. 6, a plurality of buried conductive layers BC3 are arranged along the Y-direction. A plurality of buried conductive layers BC3 are in contact with one buried conductive layer BC2.

As shown in FIGS. 6 and 7, an interlayer insulating layer IL1c is disposed on the upper surface of the interlayer insulating layer IL1b. The interlayer insulating layer IL1c is provided with a wiring trench VH2a (first wiring trench) and a wiring trench VH2b (second wiring trench).

The wiring trench VH2a penetrates the interlayer insulating layer IL1c so as to reach the buried conductive layer BC3 from the upper surface of the interlayer insulating layer IL1c. Source wiring SICs are buried in the wiring trench VH2a. The source wiring SIC is in contact with the buried conductive layer BC3.

The wiring trench VH2b penetrates the interlayer insulating layer IL1c. The drain wiring DIC is buried in the wiring trench VH2b.

As shown in FIG. 3, the source wiring SIC is electrically connected to each of the source region SR and the base contact region BCR through the buried conductive layer BC1-BC3. The source wiring SIC is connected to a plurality of buried conductive layers BC3 arranged in the X-direction.

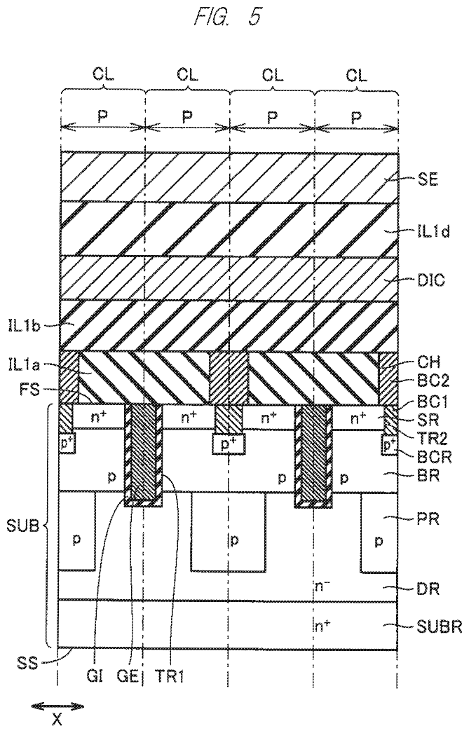

As shown in FIGS. 3 and 5, each of the source wiring SIC and the drain wiring DIC extends in the X-direction while contacting the upper surface of the interlayer insulating layer IL1b.

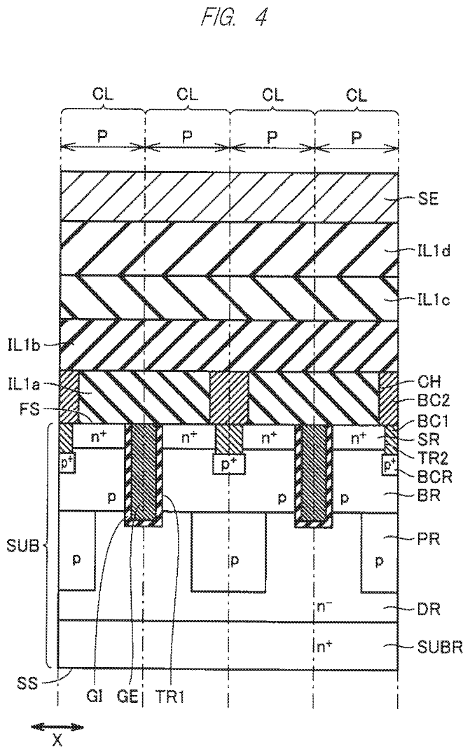

As shown in FIGS. 4, 6, and 7, an interlayer insulating layer IL1c is disposed between the source wiring SIC and the drain wiring DIC. The source wiring SIC and the drain wiring DIC are adjacent to each other with the interlayer insulating layer IL1c interposed therebetween, whereby a capacitance is formed between the source wiring SIC and the drain wiring DIC.

As shown in FIGS. 3 and 7, an interlayer insulating layer IL1d is disposed on the upper surface of the interlayer insulating layer IL1c. A via hole VH3 is provided in the interlayer insulating layer IL1d. The via hole VH3 penetrates the interlayer insulating layer IL1d from the upper surface of the interlayer insulating layer IL1d to reach the source wiring SIC. A buried conductive layer BC5 is buried in the via hole VH3. The buried conductive layers BC5 are in contact with the source wiring SICs.

Source electrodes SEs are arranged on the upper surface of the interlayer insulating layer IL1d. The source electrode SE is in contact with the buried conductive layer BC5. The source electrodes SEs are electrically connected to the source wiring SICs and the source regions SRs through the buried conductive layers EC5.

As shown in FIGS. 5 to 7, the source electrode SE covers the drain wiring DIC above the drain wiring DIC with the interlayer insulating layer IL1d interposed between the source electrode SE and the drain wiring DIC. Since the source electrode SE and the drain wiring DIC face each other with the interlayer insulating layer IL1d interposed therebetween, a capacitance is formed between the source electrode SE and the drain wiring DIC.

As shown in FIG. 13, the drain electrode DE and the gate wiring GEI are arranged on the upper surface of the interlayer insulating layer IL1d in addition to the source electrode SE. The drain electrodes DE are electrically connected to the substrate region SUBR serving as a drain of the substrate region. The gate wiring GEI is electrically connected to the gate electrode GE.

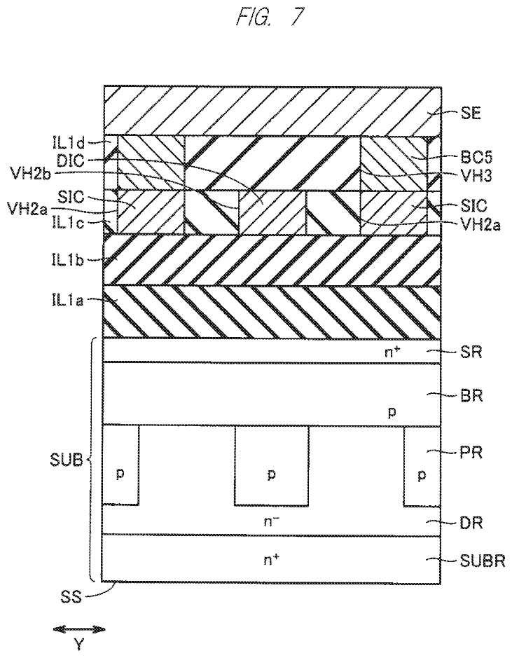

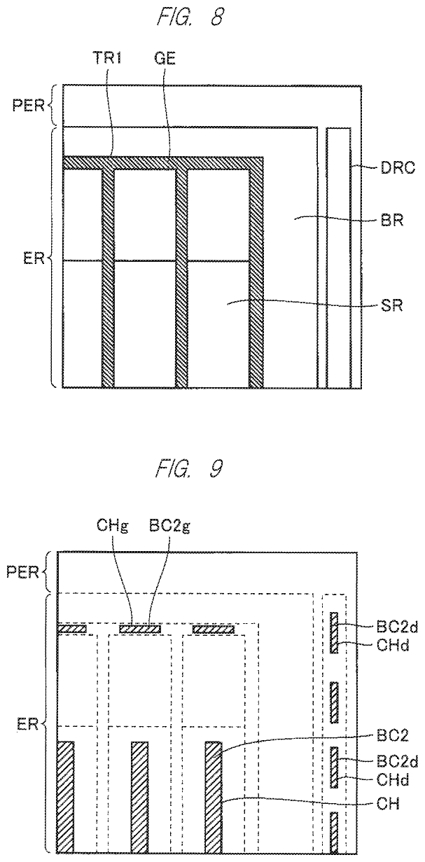

Next, a connection structure between the drain electrode DE and the substrate region SUBR, and a connection structure between the drain electrode DE and the substrate region SUBR and between the gate wiring GEI and the gate electrode GE will be described with reference to FIGS. 8 to 15.

As shown in FIG. 8, in the element region ER, the gate electrode GE is disposed so as to surround the periphery of the source region SR). The drain contact region DRC is arranged in the outer peripheral region PER.

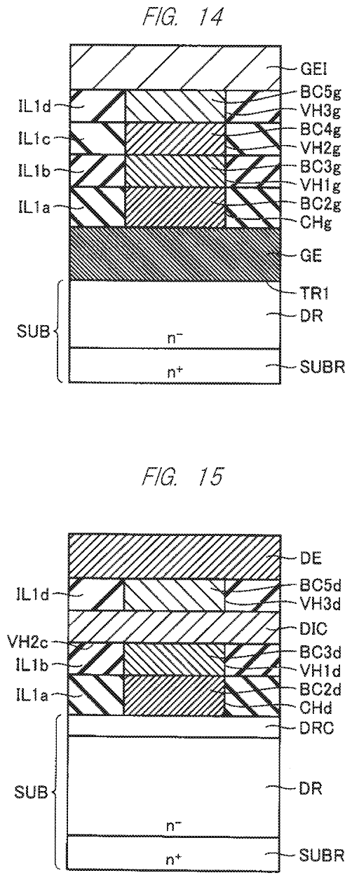

As shown in FIG. 14, the gate electrodes GE are buried in the gate trenches TR1. As shown in FIG. 15, the drain contact region DRC is electrically connected to the substrate region SUBR serving as the drain region through the drift region DR.

The drain contact region DRC is disposed on the first surface FS of the semiconductor substrate SUB.

As shown in FIGS. 9, 14 and 15, contact holes CHg and CHd are formed in the interlayer insulating layer IL1a on the first surface FS of the semiconductor substrate SUB.

As shown in FIG. 14, the contact hole CHg penetrates the interlayer insulating layer IL1a so as to reach the gate electrode GE from the upper surface of the interlayer insulating layer IL1a. A buried conductive layer BC2g is disposed in the contact hole CHg. The buried conductive layers BC2g are in contact with the gate electrodes GE.

As shown in FIG. 15, the contact hole CHd penetrates the interlayer insulating layer IL1a so as to reach the drain contact area DRC from the upper surface of the interlayer insulating layer IL1a. A buried conductive layer BC2d is disposed in the contact hole CHd. The buried conductive layers BC2d are in contact with the drain contact regions DRCs.

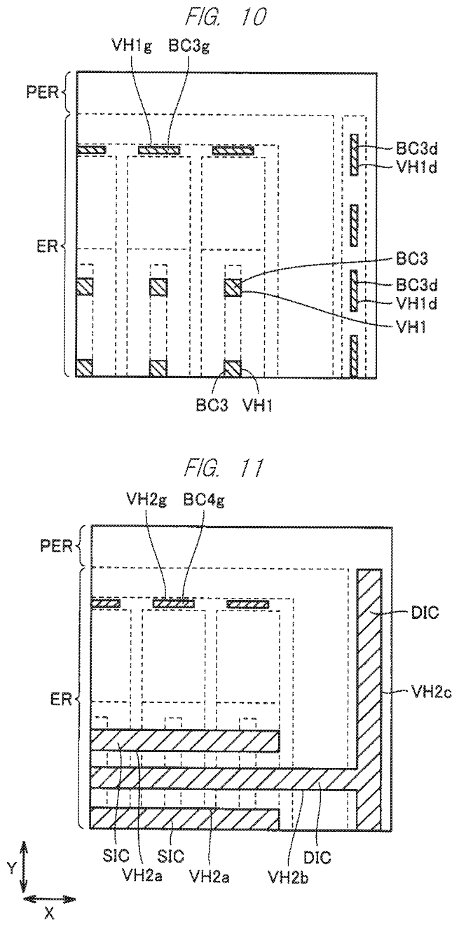

As shown in FIGS. 10, 14, and 15, via holes VH1g and VH1d are provided in the interlayer insulating layer IL1b on the upper surface of the interlayer insulating layer IL1a.

As shown in FIG. 14, the via hole VH1g penetrates the interlayer insulating layer IL1b so as to reach the buried conductive layer BC2g from the upper surface of the interlayer insulating layer IL1b. A buried conductive layer BC3g is disposed in the via hole VH1g. The buried conductive layer BC3g is in contact with the buried conductive layer BC2g.

As shown in FIG. 15, the via hole VH1d penetrates the interlayer insulating layer IL1b so as to reach the buried conductive layer BC2d from the upper surface of the interlayer insulating layer IL1b. A buried conductive layer BC3d is disposed in the via hole VH1d. The buried conductive layer BC3d is in contact with the buried conductive layer BC2d.

As shown in FIG. 11, FIG. 14, and FIG. 15, the wiring trenches VH2a and VH2b, the VH2c, and the via holes VH2g are provided in the interlayer insulating layer IL1c on the upper surface of the interlayer insulating layer IL1b.

As shown in FIG. 11, the wiring trench VH2c extends in the Y-direction. For example, the wiring trench VH2c extends in a direction perpendicular to the X direction in which the wiring trench VH2b extends.

As shown in FIG. 15, the wiring trench VH2c penetrates the interlayer insulating layer IL1c from the upper surface of the interlayer insulating layer IL1c to reach the plurality of buried conductive layers BC3d. The drain wiring DIC is buried in the wiring trench VH2c.

As shown in FIG. 11, the drain wiring DIC the via hole VH2 extends in the Y direction, and the drain wiring is in contact with the plurality of buried conductive layers BC3d arranged in the Y direction. The drain wiring DIC in the wiring trench VH2c and the drain wiring DIC in the wiring trench VH2b are connected to each other.

As shown in FIG. 14, the via hole VH2g penetrates the interlayer insulating layer IL1c so as to reach the buried conductive layer BC3g from the upper surface of the interlayer insulating layer IL1c. A buried conductive layer BC4g is buried in the via hole VH2g. The buried conductive layer BC4g is in contact with the buried conductive layer BC3g.

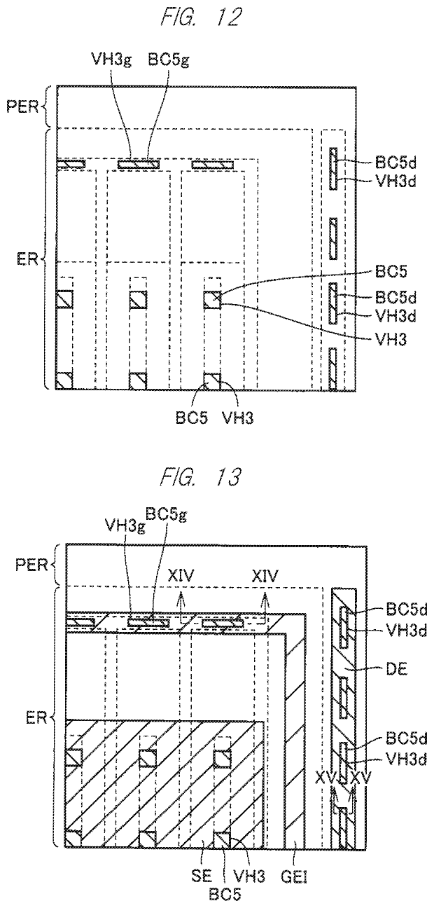

As shown in FIGS. 12, 14, and 15, via holes VH3, a VH3d, and a VH3g are provided in the interlayer insulating layer IL1d on the upper surface of the interlayer insulating layer IL1c. A plurality of via holes VH3 reach one source wiring SIC. A buried conductive layer BC5 is buried in each of the plurality of via holes VH3.

As shown in FIG. 15, the plurality of via holes VH3d penetrate the interlayer insulating layer IL1d from the upper surface of the interlayer insulating layer IL1d so as to reach the drain wiring DIC in the wiring trench VH2c. A buried conductive layer BC5d is buried in each of the plurality of via holes VH3d. Each of the plurality of buried conductive layers BC5d is in contact with the drain wiring DIC in the wiring trench VH2c.

As shown. in FIG. 14, the via hole VH3g penetrates the interlayer insulating layer IL1d so as to reach the buried conductive layer BC4g from the upper surface of the interlayer insulating lays IL1d. A buried conductive layer BC5g is buried in each of the plurality of via holes VH3g. The buried conductive layer BC5g is in contact with the buried conductive layer BC4g.

As shown in FIG. 13, 14, and 15, the source electrode SE, the drain electrode DE, and the gate wiring GEI are arranged on the upper surface of the interlayer insulating layer IL1d. The source electrode SE is disposed in the device region ER so that the source electrode SE is in contact with the plurality of buried conductive layers BC5 in the device region ER.

The gate wiring GEI surrounds the outer periphery of the source electrode SE in the element region ER in plan view. The gate wiring GEI is arranged so that the gate wiring GEI is in contact with the plurality of buried conductive layers EC5g The drain electrode DE is arranged so as to extend linearly in the outer peripheral region. The drain electrode DE is disposed so that the drain electrode DE is in contact with the plurality of buried conductive layers EC5d.

As shown in FIG. 15, the drain electrode DE is electrically connected the substrate region SUBR through buried conductive layers BC2g and BC3g, the drain electrode DE is electrically connected to the substrate region EC2g through the buried conductive layers BC4g and BC5g. As shown in FIG. 14, the gate wiring GEI are electrically connected to the gate electrodes GE through the buried conductive layers BC2d and BC3d, the EC5d wiring DIC, and the drain wiring DIC.

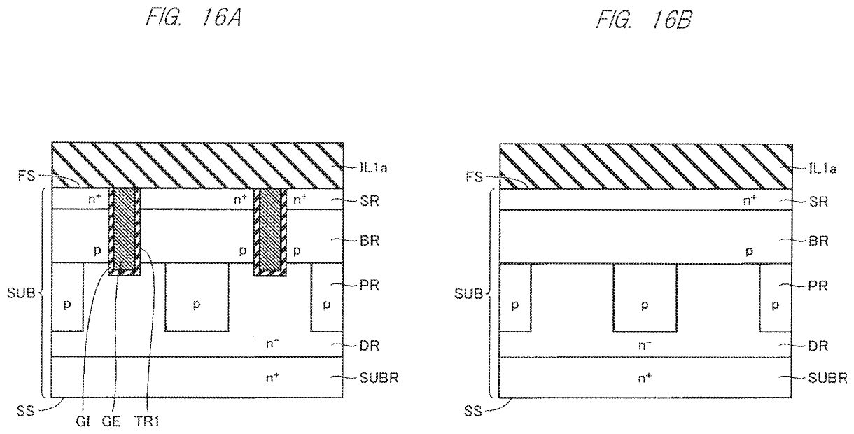

Next, a method of manufacturing a semiconductor device according to the present embodiment will be described with reference to FIGS. 16A, 16B, 17A, 17B, 18A, 18B, 19A, 19B, 20A, 20B, 21A, 21B, 22A, 22B, 23A, 23B, 24A, 24B, 25A, 25B, 26A, 26B, 27A, and 27B and the like. FIGS. 16A, 17A, 18A, 19A, 20A, 21A, 22A, 23A, 24A, 25A, 26A, and 27A show a manufacturing process corresponding to the cross section of FIG. 3, FIGS. 16B, 17B, 18B, 19B, 20B, 21B, 22B, 23B, 24B, 25B, 26B, and 27B show a manufacturing process corresponding to the cross section of FIG. 6.

As shown in FIGS. 16A and 16B, a semiconductor substrate SUB having a first surface FS and a second surface SS facing each other is prepared. A plurality of trench-gate-type vertical MOSFET cells CLs are formed in the semiconductor substrate SUB.

Each of the plurality of MOSFET cells CLs is formed to have at least a substrate region SUBR, a drifting region DR, a base region BR, a source region SR, gate electrodes GE, and a gate insulating layer GI. Each of the plurality of cells CL may be formed to have a buried p-type region PR.

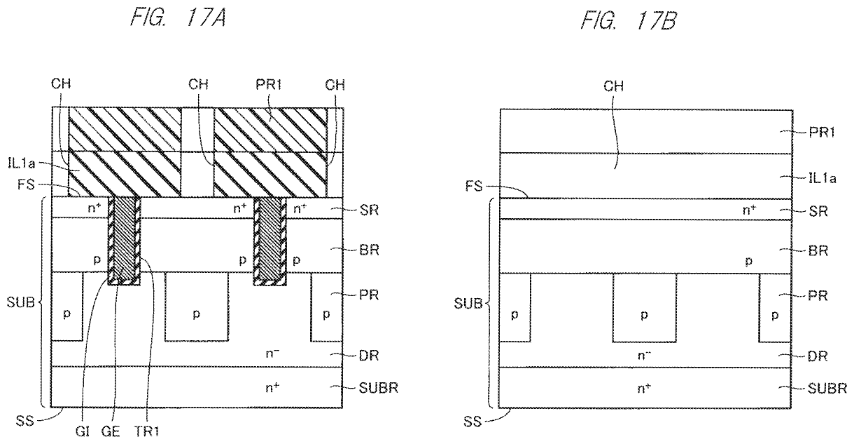

An interlayer insulating layer IL1a is formed on the first surface FS of the semiconductor substrate SUB. As shown in FIGS. 17A and 17B, a photo-resist PR1 is applied on the interlayer insulating layer IL1a. The photo resist PR1 is patterned by photolithography. Using the patterned photo resist PR1 as a mask, the interlayer insulating layer IL1a is etched. By this etching, the contact hole CH, the contact hole CHd, and the contact hole CHg are formed.

contact hole CH is formed from the upper surface of the interlayer insulating layer IL1a to the first surface FS of the semiconductor substrate SUB. As shown in FIG. 9, the contact hole CH is formed so that the width (dimension) in the Y direction is larger than the width (dimension) in the X direction.

As shown in FIG. 15, the contact hole CHd is formed so as to reach the drain contact area DRC from the upper surface of the interlayer insulating layer IL1a. As shown in FIG. 14, the contact hole CHg is formed so as to reach the gate electrode GE from the upper surface of the interlayer insulating layer IL1a. Thereafter, the photo-resist PR1 is removed by, for example, ashing.

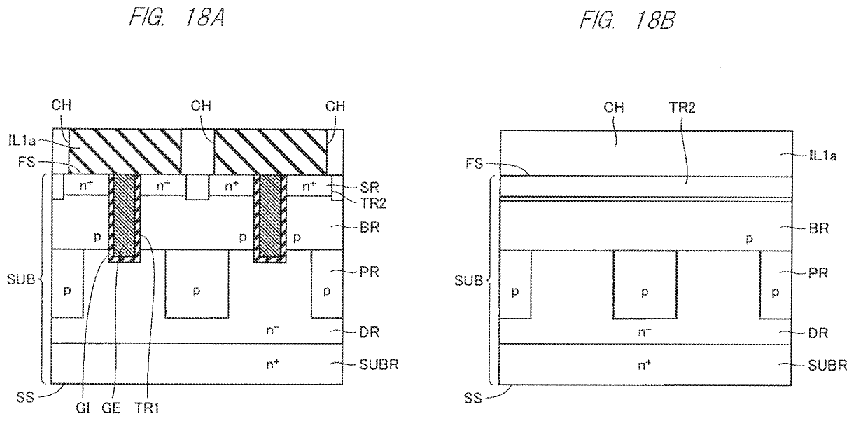

As shown in. FIGS. 18A and 18B, the first surface FS of the semiconductor substrate SUB exposed from the contact hole CH is etched using the interlayer insulating layer IL1a as a mask. By this etch, a source trench TR2 is formed on the first surface FS. The source trench TR2 is formed so as to penetrate the source region SR from the first surface FS and reach the base region BR.

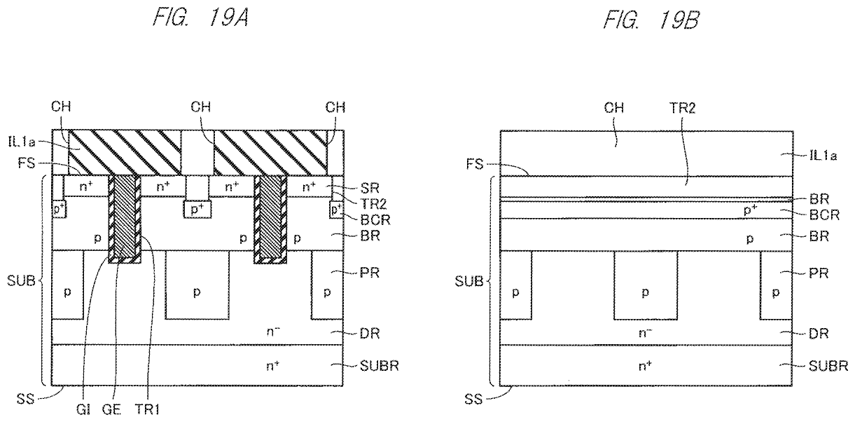

As shown in FIGS. 19A and 19B, type impurities are ion-implanted into the exposed base region BR through the contact hole CH and the source trench TR2. As a result, the base contact regions BCRs are formed at the bottom portions of the source trenches TR2. The base contact region BCR is formed to have a higher p-type impurity concentration than the base region BR in the base region BR. As described above, each of the plurality of cells CL may be formed to have the base contact region BCR.

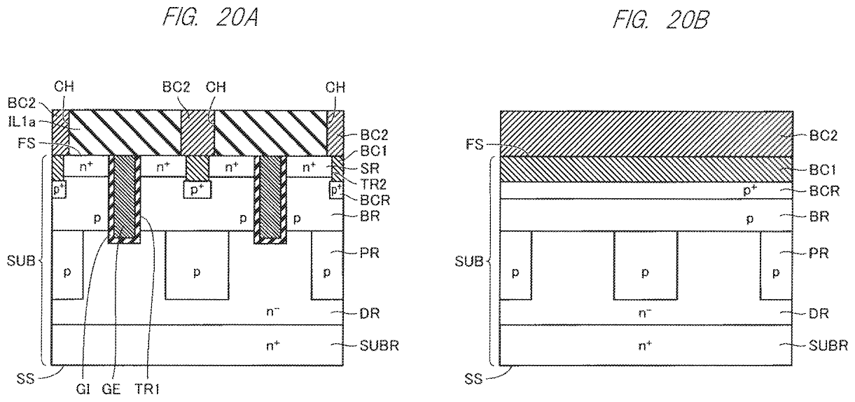

As shown in FIGS. 20A and 20B, buried conductive layer BC1 are formed in the source trenches TR2. A buried conductive layer BC2 is formed in the contact hole CH. The buried conductive layers BC1 and BC2 may be formed simultaneously as an integral conductive layer. In this case, this integral conductive layer becomes the first buried conductive layer. As shown in FIG. 9, the embedded conductive layers BC1 and BC2 are formed so that the width (dimension) in the Y direction is larger than the width (dimension) in the X direction

As shown in FIG. 15, buried conductive layers BC2d are formed in the contact holes CHd. As shown in FIG. 14, buried conductive layers BC2g are formed in the contact holes CHg.

The buried conductive layers BC2, the buried conductive layers BC2d, and the buried conductive layers BC2g are formed at the same time, for example. Specifically, a conductive layer is formed on the upper surface of the interlayer insulating layer IL1a so as to fill the contact holes CH, CHd, and CHg. Thereafter, the conductive layer is removed by, for example, Chemical Mechanical Etching until the upper surface of the interlayer insulating layer IL1a is exposed. As a result, the conductive layer remains in the contact holes CH, CHd, and CHg, and buried conductive layers BC2, and BC2d, and BC2g are formed at the same time.

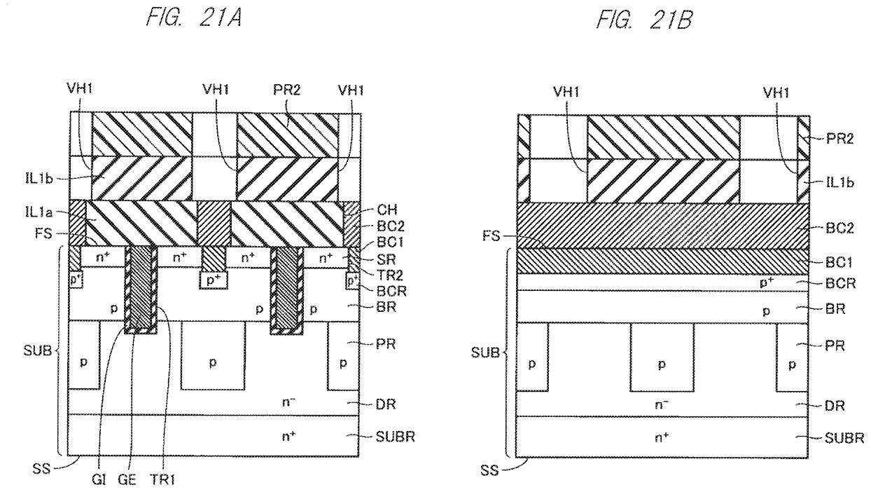

As shown in FIGS. 21A and 21B, an interlayer insulating layer IL1b (first insulating layer) is formed on the interlayer insulating layer IL1a. A photo-resist PR2 is applied over the interlayer insulating layer IL1b. The photo resist PR2 is patterned by photolithography. Using the patterned photo resist PR2 as a mask, the interlayer insulating layer IL1b is etched. By this etch, the via hole VH1, the via hole VH1d, and the via hole VH1g are formed.

The via hole VH1 is formed so as to reach the buried conductive layer B2 from the upper surface of the interlayer insulating layer IL1b. As shown in FIGS. 10 and 15, the via hole VH1d is formed so as to reach the buried conductive layer BC2d from the upper surface of the interlayer insulating layer IL1b. As shown in FIGS. 10 and 14, the via hole VH1g is formed so as to reach the buried conductive layer BC2g from the upper surface of the interlayer insulating layer IL1b.

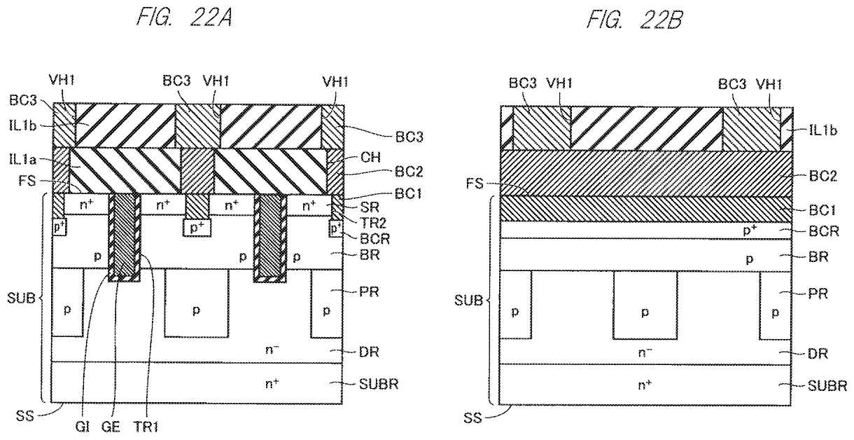

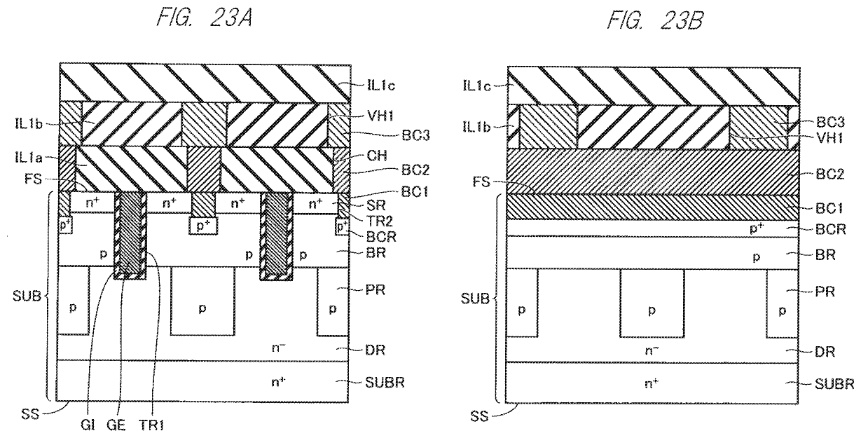

Thereafter, the photo-resist PR2 is removed by, for example, ashing. As shown in FIGS. 22A and 22B, the buried conductive layer BC3 (second buried conductive layer) is formed in the via hole VH1. As shown in FIGS. 11 and 15, buried conductive layers BC3d are formed in the via holes VH1d. As shown in FIGS. 11 and 14, buried conductive lays are formed in the via holes VH1g.

The buried conductive layers BC3, the buried conductive layers BC3d, and the buried conductive layers BC3g are formed at the same time, for example. More specifically, a conductive layer is formed on the upper surface of the interlayer insulating layer IL1b so as to bury the via holes VH1, the VH1d, and the VH1g. Thereafter, the conductive layer is removed by, for example, CMP until the upper surface of the interlayer insulating layer IL1b is exposed. As a result, the conductive layers remain in the via holes VH1, the via holes VH1d, and the via holes VH1g, and the buried conductive layers BC3, the buried conductive layers BC3d, and the buried conductive layers BC39 are simultaneously formed.

As shown in FIGS. 23A and 23B, an interlayer insulating layer IL1c is formed on the interlayer insulating layer IL1b.

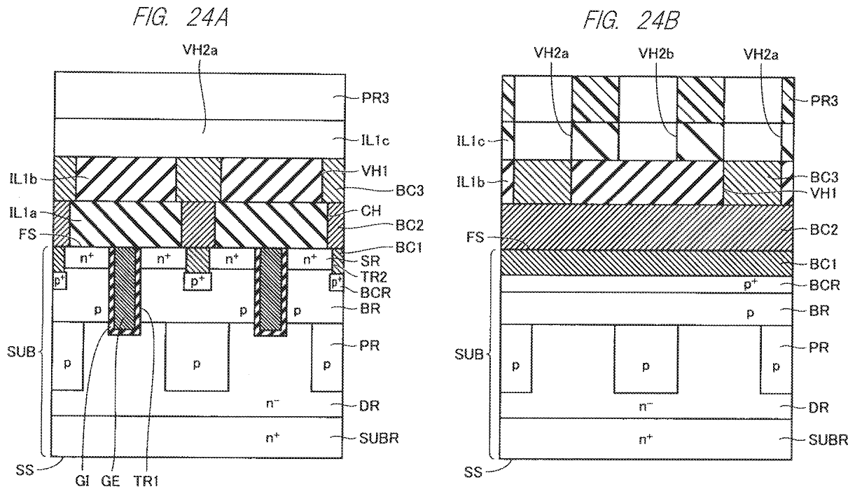

As shown in FIGS. 24A and 24B, a photo-resist PR3 is applied on the interlayer insulating layer IL1c. The photo resist PR3 is patterned by photolithography. Using the patterned photo resist PR3 as a mask, the interlayer insulating layer IL1c is etched. By this etch, the wiring trenches VH2a and VH2b, the VH2c and the via hole VH2g are formed in the interlayer insulating layer IL1c.

The wiring trench VH2a (first wiring trench) is formed to extend in the X-direction (FIG. 11) and to reach the plurality of buried conductive layers BC3 from the upper surface of the interlayer insulating layer IL1c. The wiring trench VH2b (second wiring trench) is formed so as to extend in the X-direction (FIG. 11) and reach the interlayer insulating layer IL1b from the upper surface of the interlayer insulating layer IL1c.

As shown in FIG. 11, the wiring trench VH2c is formed to extend in the Y-direction and to be connected to the wiring trench VH2b. As shown in FIGS. 11 and 15, the wiring trench VH2c is formed so as to reach the plurality of buried conductive layers BC3d from the upper surface of the interlayer insulating layer IL1c.

As shown in FIG. 14, the via hole VH2g is formed so as to reach the buried conductive layer BC3g from the upper surface of the interlayer insulating layer IL1c.

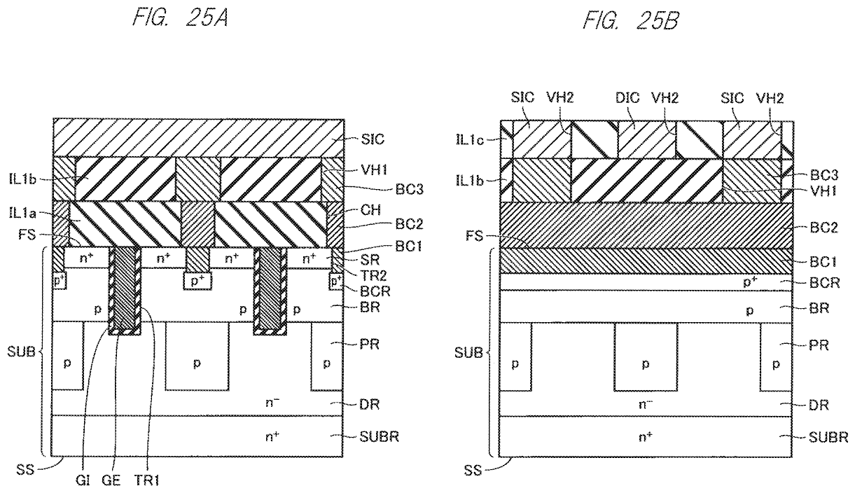

Thereafter, the photo-resist PR3 is removed by, for example, ashing. As shown in FIGS. 25A and 25B, the source wiring SICs are formed in the wiring trench VH2a. The source wiring SIC is formed so that the source wiring SIC is in contact with the plurality of buried conductive layers BC3.

The drain wiring DIC is formed in the wiring trench VH2b.

As shown in FIG. 11, the source wiring SIC and the drain wiring DIC in the wiring trench VH2b are formed so as to extend in the X direction and to form a capacitor adjacent to each other in the Y direction. More specifically, as shown in FIG. 25B, the source wiring SIC and the drain wiring DIC in the wiring trench VH2b are adjacent to each other in the Y-direction with the interlayer insulating layer IL1c interposed therebetween, thereby forming a capacitor.

As shown in FIGS. 11 and 15, the drain wiring DIC is formed in the wiring trench VH2c. The drain wiring DIC in the wiring trench VH2c is formed so that the drain wiring DIC is in contact with the buried conductive layer BC3d. The drain wiring DIC in the wiring trench VH2c is formed so as to be integrated with the drain wiring DIC in the wiring trench VH2b.

As shown in FIGS. 11 and 14, buried conductive layers BC4g are formed in the via holes VH2g. The buried conductive layer BC4g formed so as to be in contact with the buried conductive layer BC3g.

The source wiring SIC, the drain wiring DIC, and the buried conductive layers BC3g are formed at the same time, for example. More specifically, a conductive layer is formed on the upper surface of the interlayer insulating layer IL1c so as to bury the wiring trenches VH2a and VH2b, the VH2c, and the via holes VH2g. Thereafter, the conductive layer is removed by, for example, CMP until the upper surface of the interlayer insulating layer IL1c is exposed. As a result, the conductive layer remains in the wiring trenches VH2a and VH2b, the VH2c, and the via hole VH2g, and the source wiring SIC, the drain wiring DIC, and the buried conductive layer BC4g are formed at the same time.

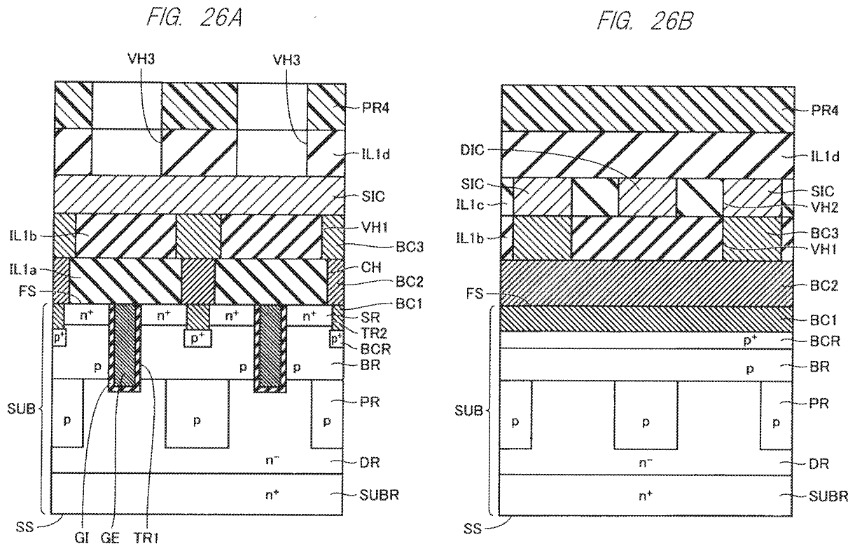

As shown in FIGS. 26A and 26B, an interlayer insulating layer IL1d (second insulating layer) is formed on the interlayer insulating layer IL1c. A photo-resist PR4 is applied over the interlayer insulating layer IL1d. The photo resist PR4 is patterned by photolithography. Using the patterned photo resist PR4 as a mask, the interlayer insulating layer IL1d is etched. By this etch, a via hole VH3, a via hole VH3d, and a via hole VH3g are formed.

The via hole VH3 is formed from the upper surface of the interlayer insulating layer IL1d to reach the source wiring SIC. As shown in FIG. 12 and FIG. 15, the via hole VH3d is formed so as to reach the drain wiring DIC in the wiring trench VH2c from the upper surface of the interlayer insulating layer IL1d. As shown in FIGS. 12 and 14, the via hole VH3g is formed so as to reach the buried conductive layer BC4g from the upper surface of the interlayer insulating layer IL1d.

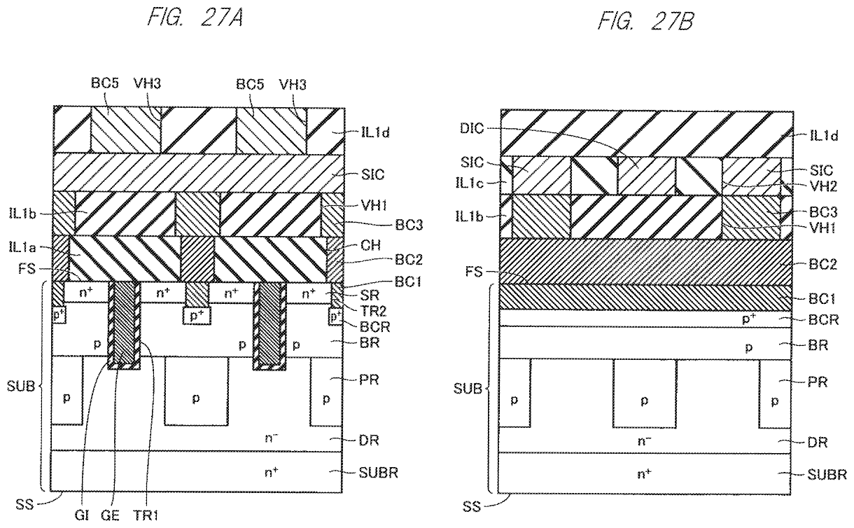

Thereafter, the photo-resist PR4 is removed by, for example, ashing. As shown in FIGS. 27A and 27B, buried conductive layers BC5 are formed in the via holes VH3. As shown in FIGS. 12 and 15, buried conductive layers BCSd are formed in the via holes VH3d. As shown in FIGS. 12 and 14, buried conductive layers BC5g are formed in the via holes VH3g.

The buried conductive layers BC5, the buried conductive layers BC5d, and the buried conductive layers BC5g are formed at the same time, for example. More specifically, a conductive layer is formed on the upper surface of the interlayer insulating layer IL1d so as to bury the via holes VH3, the VH3d, and the VH3g. Thereafter, the conductive layer is removed by, for example, CMP until the upper surface of the interlayer insulating layer IL1d is exposed. As a result, the conductive layers remain in the via holes VH3, the via holes VH3d, and the via holes VH3g, and the buried conductive layers BCS, the buried conductive layers BC5d, and the buried conductive layers BC5g are simultaneously formed.

As shown in FIGS. 3 and 13, the source electrode SE, the drain electrode DE, and the gate wiring GEI are formed on the interlayer insulating layer IL1d. The source electrode SE is formed so that the source electrode SE is in contact with the buried conductive layer BCS. Thus, the source electrode SE is electrically connected to the source region SR.

The drain electrode DE is formed so that the drain electrode DE is in contact with the buried conductive layer BC5d. As a result, the drain electrodes DE are electrically connected to the substrate region SUBR serving as a drain of the substrate region SUBR.

The gate wiring GEI is formed so that the gate wiring GEI is in contact with the buried conductive layer BC5 Thus, the gate wiring GEI is electrically connected to the gate electrode

The source electrode SE, the drain electrode DE, and the gate wiring GEI are formed at the same time, for example. Specifically, a conductive layer is formed on the interlayer insulating layer IL1d. Thereafter, a photoresist (not shown) is applied on the conductive layer. The photoresist is patterned by photolithography. The conductive layer is etched using the patterned photoresist as a mask. Thereby, the conductive layer is patterned, and a source electrode SE, a drain electrode DE, and a gate wiring GEI are simultaneously formed from the conductive layer. Thereafter, the photoresist is removed by, for example, ashing.

As described above, the semiconductor device of the present embodiment is manufactured. Next, the operation and effect of the present embodiment will be described.

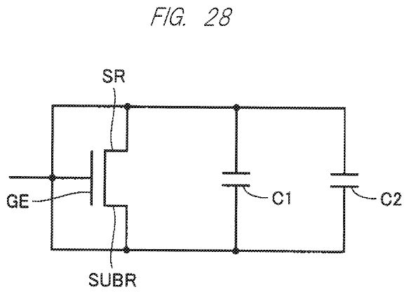

In the present embodiment, as shown in FIG. 2, FIG. 6, and FIG. 11, the drain wiring DIC and the source wiring SIC extend in the X direction (first direction) and mutually adjoin each other in the Y direction (second direction) intersecting the X direction to constitute a capacitor. As a result, as shown in FIG. 28, the additional capacitance C1 between the drain wiring DIC and the source wiring SIC is connected in parallel with the junction capacitance C2 between the base region BR and the drift region DR. Therefore, in the present embodiment, the influence of noise is reduced by the additional capacitance C1.

In the present embodiment, as shown in FIG. 2, the drain wiring DIC and the source wiring SIC extend in the X direction in which the plurality of MOSFET cells CL are arranged. Therefore, even when a pitch P of each cell CL is reduced for high integration, the distance between the drain wiring DIC and the source wiring SIC is not reduced. Therefore, even when the shrinkage of the MOSFET cell CL progresses, it is easy to secure the breakdown voltage between the drain wiring DIC and the source wiring SIC.

In addition, in the present embodiment, as shown in FIG. 2, a conductive layer BC3 which is in contact with both the buried conductive layer 2 extending in the Y direction and the source wiring SIC extending in the X direction is arranged in the upper layer of the buried conductive layer BC2 and in the lower layer of the source wiring SIC. By arranging the buried conductive layer BC3 in this manner, the source wiring can be extended in a direction differing from the extension direction of the buried conductive layer BC2 in the upper layer of the buried conductive layer BC2. A capacitance can be formed between the source wiring SIC and the drain wiring DIC by extending the drain wiring in the X direction so as to run in parallel with the source wiring SIC. By extending the drain wiring DIC in the upper layer of the buried conductive layer BC2 differently from the buried conductive layer BC2 in this manner, even when the pitches P of the cells CL are reduced, a configuration in which the distances between the drain wiring DIC and the source wiring SIC are not reduced can be realized.

In the present embodiment, as shown in FIG. 2, the width (dimension) in the Y direction of the buried conductive layer BC2 is larger than the width (dimension) in the X direction of the buried conductive layer BC2 in plan view. As a result, a large contact area with the source region SR can be ensured. Therefore, it is possible to reduce the resistances of the contacts between the buried conductive layers BC2 and the source regions SRs.

In the present embodiment, as shown in FIG. 3, the source electrodes SEs electrically connected to the source wiring SIC cover the drain wiring DIC with the interlayer insulating layer IL1d interposed therebetween. As a result, a capacitance can be formed between the drain wiring DIC and the source electrode SE. This makes it possible to further reduce the influence of noise.

In the present embodiment, as shown in FIG. 6, each of the source wiring SIC and the drain wiring DIC is disposed inside the wiring trenches VH2a and VH2b provided in the interlayer insulating layer IL1c. This makes it possible to manufacture the present configuration by a so-called damascene process.

Although MOSFET has been described above, the gate insulating layer GI is not limited to silicon oxide, and the gate insulating layer may be made of a material containing silicon nitride.

Although the invention made by the present inventor has been specifically described based on the embodiment, the present invention is not limited to the embodiment described above, and it is needless to say that various modifications can be made without departing from the gist thereof.

What is claimed is:

1. A semiconductor device comprising: a semiconductor substrate having a first surface and a second surface opposing each other;
a plurality of cells each having a source region disposed in the first surface and a drain region disposed in the second surface;
a first insulating layer disposed on the first surface;
a drain wiring electrically connected to the drain region and disposed in contact with an upper surface of the first insulating laver; and
a source wiring electrically connected to the source region and disposed in contact with the upper surface of the first insulating laver, wherein the plurality of cells are disposed side by side in a first direction, and
wherein the drain wiring and the source wiring extend in the first direction and form a capacitor adjacent to each other in a second direction intersecting the first direction.

2. The semiconductor device of claim 1, further comprising: a first buried conductive layer electrically connected to the source region and extending in the second direction on the first surface;
and a second buried conductive layer located on the first buried conductive layer below the source wiring and in contact with both the first buried conductive layer and the source wiring.

3. The semiconductor device of claim 2, wherein a dimension of the first buried conductive layer in the second direction in plan view is larger than a dimension of the first buried conductive layer in the first direction in plan view.

4. The semiconductor device of claim 1, further comprising a source electrode electrically connected to the source wiring and covering an upper portion of the drain wiring.

5. The semiconductor device of claim 1, further comprising a second insulating layer disposed on the first insulating layer,
the second insulating layer having a first wiring trench and a second wiring trench,
the source wiring disposed in the first wiring trench, and the drain wiring disposed in the second wiring trench.

6. A method of manufacturing a semiconductor device, the method comprising:
providing a semiconductor substrate having first and second surfaces facing each other;
forming a plurality of cells in the semiconductor substrate, each cell having a source region disposed in the first surface and a drain region disposed in the second surface;
forming a first insulating layer on the first surface;
forming a drain wiring electrically connected to the drain region in contact with an upper surface of the first insulating layer; and forming a source wiring electrically connected to the source region in contact with an upper surface of the first insulating layer,
wherein the plural of cells are arranged side by side in a first direction, and the drain wiring and the source wiring are formed so as to form a capacitor adjacent to each other in a second direction extending in the first direction and intersecting the first direction.

7. The method of manufacturing a semiconductor device according to claim 6, further comprising: forming a first buried conductive layer electrically connected to the source region and extending in the second direction on the first surface; and forming a second buried conductive layer located on the first buried conductive layer below the source wiring and in contact with both the first buried conductive layer and the source wiring.

8. The method of manufacturing a semiconductor device according to claim 7, wherein the first buried conductive layer is formed so that the dimension in the second direction is larger than the dimension in the first direction in plan view.

9. The method of manufacturing a semiconductor device according to claim 6, further comprising the step of forming a source electrode electrically connected to the source wiring and covering the upper portion of the drain wiring.

10. The method of manufacturing a semiconductor device according to claim 6, further comprising: forming a second insulating layer disposed on the first insulating layer; and
forming a first wiring trench and a second wiring trench in the second insulating layer,
wherein the source wiring is formed in the first wiring trench, and the drain wiring is formed in the second wiring trench.
